(19) United States
(12) Patent Application Publication
(10) Pub. No.: US 2017/0320229 A1
(43) Pub. Date: Nov. 9, 2017

(54) INTEGRATED WOODWORKING SYSTEM

(71) Applicant: PRECISION MACHINERY RESEARCH & DEVELOPMENT CENTER, Taichung (TW)

(72) Inventors: Bing-Chi JAN, TAICHUNG (TW); Lih-Jung CHOU, TAICHUNG (TW); Ching-Liang FANG, TAICHUNG (TW); Chia-Ping HO, TAICHUNG (TW)

(21) Appl. No.: 15/586,556

(22) Filed: May 4, 2017

(30) Foreign Application Priority Data
May 4, 2016 (TW) 105113884

(51) Int. Cl. B27C 9/00; G01R 21/00; B25H 3/00

(52) U.S. Cl. CPC B27C 9/005; B25H 3/00; G01R 21/007

(57) ABSTRACT

An integrated woodworking system connectable to an external source of electricity includes an enclosure, a management and control center, and plural tool holders. The management and control center is provided in the enclosure; is connectable to the source of electricity and a source of gas pressure; can control the consumption of input electricity, the flow rate of input gas, and a pneumatic tool such as a dust collector; and has at least one electricity output cable and at least one gas output hose. The tool holders are provided in the enclosure and are each connected to the electricity output cable or the gas output hose. The system incorporates the woodworking tools one needs into the enclosure and can be sold as a whole to save the trouble of purchasing and installing the tools individually. By managing power consumption in general, the system prevents overloading.

### BACKGROUND OF THE INVENTION

### 1. Technical Field

The present invention relates to a system of woodworking equipment. More particularly, the present invention relates to a modular integrated woodworking system where various pieces of woodworking equipment are incorporated into a single enclosure so that not only can the cables and hoses of the equipment in the enclosure be arranged as a whole, but also power consumption and all the pneumatic equipment (e.g., a dust collector) can be monitored and managed with ease.

### 2. Description of Related Art

Conventionally, one who wishes to perform a carpentry project would go to a woodworking tool manufacturer or shop to buy the necessary tools, and then carry out the woodworking activities in a chosen working environment 70 (e.g., a personal workshop or garage) as shown in FIG. 1. As the working environment 70 may lack a comprehensive planning or be inadequately equipped in the first place, the following drawbacks are likely to be found:

1. Due to the absence of proper planning, one who is working in the working environment 70 tends to use whichever source of electricity 71 they can find in order to operate an electric drill 72, electric saw 73, or computer 74. Likewise, a pneumatic nail gun 75 or dust collector 76 to be used is usually connected to a source of gas pressure 77 that is fetched impromptu. Consequently, the cables and hoses of those tools may run all over the place, inviting accidents and making it difficult to control the overall electrical load.

2. Now that a well-designed dust collection system is not in place, the collection of wood chips and dust may be incomplete, and risks associated with flammable dust are therefore high.

3. When the working environment 70 needs expansion or an addition of woodworking tools, the initial conditions of the working environment 70 may hinder their implementation such that the environment cannot be utilized to the greatest extent.

4. Woodworking tools are typically purchased and installed one at a time, which is very inconvenient.

In view of the above, the conventional woodworking environments and the use of such an environment still leave room for improvement.

### BRIEF SUMMARY OF THE INVENTION

One objective of the present invention is to provide an integrated woodworking system where all the woodworking tools one needs are incorporated into an enclosure. The entire system can be sold as a product to spare the buyer the trouble of having to purchase and install the tools separately.

Another objective of the present invention is to provide an integrated woodworking system which improves the cable and hose arrangement of woodworking tools, which features ease and safety of use, and which allows the electrical loads of the system to be managed as a whole.

To achieve the foregoing objectives, the present invention provides an integrated woodworking system connectable to an external source of electricity, wherein the integrated woodworking system includes an enclosure, a management and control center, and a plurality of tool holders. The management and control center is provided in the enclosure and is connectable to the source of electricity and a source of gas pressure. The management and control center is configured to control the consumption of electricity input from the source of electricity and the flow rate of gas input from the source of gas pressure. The management and control center further has at least one electricity output cable and at least one gas output hose. The tool holders are provided in the enclosure and are each connected to the electricity output cable or the gas output hose.

According to the present invention, the management and control center distributes electricity or gas to each tool holder through the corresponding cable or hose and thus manages the electricity and gas used by the entire system. The present invention, therefore, not only improves the way cables and hoses are conventionally arranged, but also makes it possible to manage the electrical loads of the system as a whole and thereby prevent accidents which may otherwise result from overloading.

In one aspect of the present invention, the enclosure may be a standard 40-foot shipping container so that the integrated woodworking system can be transported worldwide through modern logistics means, e.g., by marine transportation and/or a container trailer. Also, the standardized dimensions of shipping containers allow the integrated woodworking system to be modularized. The interior layout of such a shipping container and the woodworking tools installed therein can be planned according to the sizes and materials of the intended workpieces as well as the user's budgets, in order for the integrated woodworking system to meet practical needs.

In another aspect of the present invention, the electricity output cable or the gas output hose may be partially embedded or installed in a lateral wall or the floor of the enclosure in advance to better arrange, and avoid a tangle of, the cables and hoses to be used.

In yet another aspect of the present invention, the management and control center may further include a power consumption monitoring unit, which in turn may include an analog/digital wattmeter and a pressure gage for example, in order for the management and control center to measure, under software- or hardware-based control, the consumption of the input electricity and the flow rate of the input gas. To ensure safe use of electricity, the power consumption monitoring unit may be so configured that, once the consumption of electricity exceeds a predetermined value, the management and control center is triggered to cut off the electricity supplied to the tool holders.

### BRIEF DESCRIPTION OF THE SEVERAL VIEWS OF THE DRAWINGS

FIG. 1 is a schematic diagram of a conventional woodworking environment; and

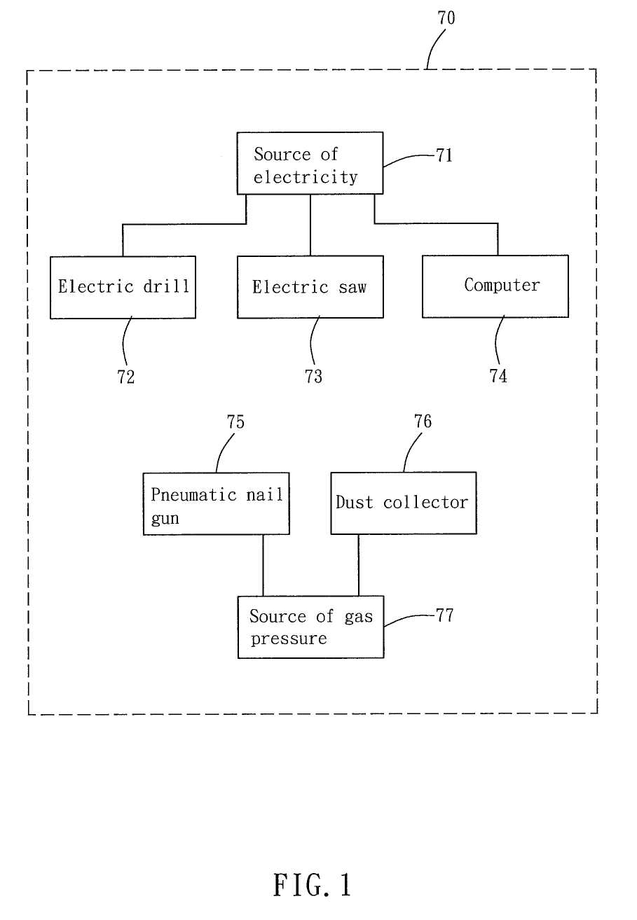

FIG. 2 schematically shows the integrated woodworking system according to a preferred embodiment of the present invention.

### DETAILED DESCRIPTION OF THE INVENTION

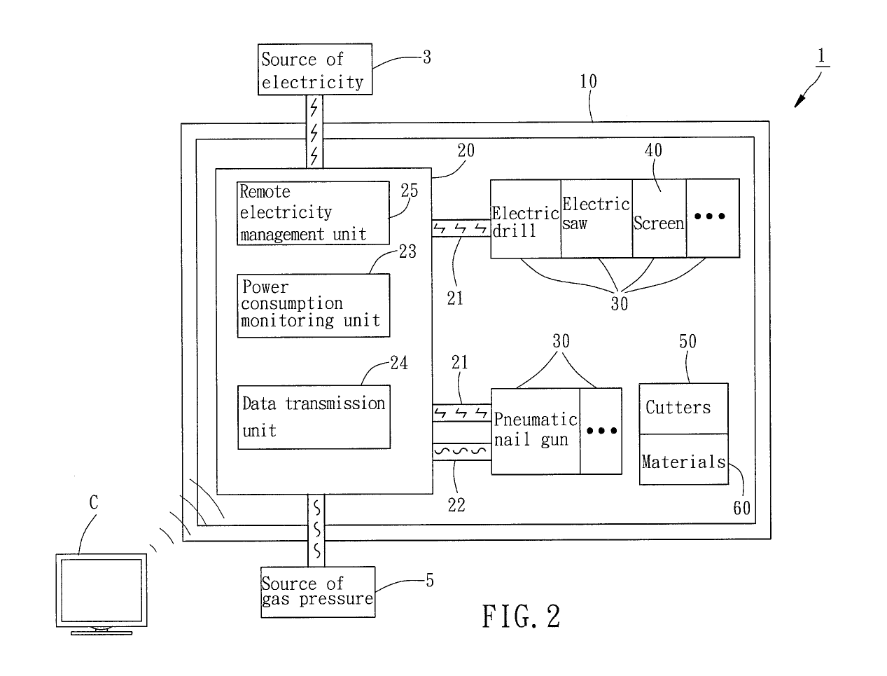

To elucidate the features of the present invention, a preferred embodiment of the invention is described below with reference to FIG. 2. The integrated woodworking system 1 is configured to connect with an external source of electricity 3 and an external source of gas pressure 5. The source of electricity 3 can be the standard 110-V or 220-V mains electricity in Taiwan but is by no means limited thereto; in other words, the source of electricity 3 may vary in specification from one country to another. The source of gas pressure 5 in this embodiment is an air compressor by way of example and is provided outside the integrated woodworking system 1. It is also feasible to place the source of gas pressure 5 inside the integrated woodworking system 1; the present invention imposes no limitations in this regard.

The integrated woodworking system 1 of the present invention essentially includes an enclosure 10, a management and control center 20, and a plurality of tool holders 30. The structures of and the relationship between these components are detailed below:

As shown in FIG. 2, the enclosure 10 is a standard 40-foot shipping container.

The management and control center 20 is provided in the enclosure 10 and is connected to the external source of electricity 3 and external source of gas pressure 5. The management and control center 20 can be a central server or an equivalent computation device and is configured to manage and control, via a conventional software or hardware control method, the consumption of electricity input from the source of electricity 3 and the flow rate of gas input from the source of gas pressure 5. For example, a central server is used to control an electronic switch for turning on and off the input of electricity, and a pressure valve for turning on and off the input of gas. The management and control center 20 further has at least one electricity output cable 21 and at least one gas output hose 22 for delivering electricity or gas to each electric or pneumatic tool mentioned further below. The electricity output cable 21 or the gas output hose 22 may be partially embedded or installed in a lateral wall of the enclosure 10 so that, by planning beforehand, all the cables and hoses to be used can be laid out in an orderly fashion.

In addition, the management and control center 20 may optionally be provided with a data transmission unit 24, a power consumption monitoring unit 23, and a remote electricity management unit 25. The data transmission unit 24 is configured to communicate with a remote computer C (e.g., a computer located at the user's residence) through a wireless or wired network, allowing the user to issue a command remotely to turn on or off the supply of electricity to the management and control center 20. When finishing a computer-aided graphic design on the computer C, the user may also send the completed CAD file to the management and control center 20 through the data transmission unit 24.

The power consumption monitoring unit 23, which may include a digital wattmeter and a pressure gage for example, is configured to measure the consumption of the input electricity and the flow rate of the input gas by a software control method or a circuit control method. Should the consumption of the input electricity exceed a predetermined value, the management and control center 20 will automatically cut off the supply of electricity to prevent accidents.

The remote electricity management unit 25 is provided in the management and control center 20. When, by operating control software remotely, the user issues a command for turning on or off the supply of electricity to the management and control center 20, the remote electricity management unit 25 will turn on or off the supply of electricity as instructed after the data transmission unit 24 receives the command and redirects the command to the remote electricity management unit 25. This allows the user to power off the integrated woodworking system 1 remotely to prevent accidents.

The tool holders 30 are provided in the enclosure 10 in a pre-planned manner and are configured to accommodate and hold various electric or pneumatic tools respectively. Each tool holder 30 is connected to either the electricity output cable 21 or the gas output hose 22, in order for the corresponding electric tool to connect electrically to the management and control center 20 through the tool holder 30 and the electricity output cable 21, or for the corresponding pneumatic tool to connect to the management and control center 20 through the tool holder 30 and the gas output hose 22. The electric tools can be electric drills, electric saws, and like woodworking tools. The pneumatic tools can be pneumatic nail guns, dust collectors, and so on. Moreover, the integrated woodworking system 1 may optionally be provided with a screen 40. The screen 40, if provided, is connected to one of the tool holders 30 so that, through a wireless network, the data transmission unit 24 can transmit a CAD file or other data to the screen 40 for display to facilitate woodworking.

It is worth mentioning that some or all of the tool holders 30 may be arranged side by side in the enclosure 10. Furthermore, a cutter storage area 50 and a material storage are 60 may be provided in the enclosure 10. The cutter storage area 50 and the material storage area 60 are each divided into a plurality of numbered sections where cutters (e.g., drill bits) or the materials to be worked on can be placed. The numbering schemes for the cutter storage area 50 and the material storage area 60 and the data of the cutters and materials placed in those areas can be synchronized with the management and control center 20 in order for the user to access and put away the cutters and materials with ease, or to enable automated retrieval and storage of the cutters and materials.

A woodworking tool vender who has received a buyer's order for the integrated woodworking system 1 can provide the buyer with a pre-planned integrated woodworking system 1 according to the sizes and materials of the workpieces the buyer intends to make as well as the buyer's budgets. The integrated woodworking system 1 may also be modularized or customized. As the integrated woodworking system 1 features a pre-planned cable and hose arrangement, the cables and hoses of the various woodworking tools in the system will not be entangled. Moreover, accidents associated with overloading are avoided thanks to the management and control center 20, which manages all the electrical loads on the electricity output cable 21 and the gas output hose 22 as a whole.

Further, the present embodiment may optionally be connected with an external water source (not shown). In that case, the system will also be provided with pipes/hoses leading from the water source to the corresponding tool holders 30 in order to supply water to those tool holders 30.

It should be pointed out that the components disclosed in the foregoing embodiment serve illustrative purposes only and are not intended to be restrictive of the scope of the present invention. All equivalent components and structural variations should be viewed as falling within the scope of the invention.

What is claimed is:

1. An integrated woodworking system, connectable to an external source of electricity, the integrated woodworking system comprising:
an enclosure;
a management and control center provided in the enclosure, wherein the management and control center is connectable to the source of electricity and a source of gas pressure, is configured to control consumption of electricity input from the source of electricity and a flow rate of gas input from the source of gas pressure, and has at least one electricity output cable and at least one gas output hose; and
a plurality of tool holders provided in the enclosure and each connected to the electricity output cable or the gas output hose, wherein each the tool holder is configured to accommodate and hold at least one electric or at least one pneumatic tool.

2. The integrated woodworking system of claim 1, wherein the source of gas pressure is located inside the integrated woodworking system.

3. The integrated woodworking system of claim 1, wherein the enclosure is a shipping container.

4. The integrated woodworking system of claim 2, wherein the management and control center further comprises a power consumption monitoring unit for measuring the consumption of the input electricity and the flow rate of the input gas.

5. The integrated woodworking system of claim 4, wherein when the consumption of the input electricity exceeds a predetermined value according to measurement of the power consumption monitoring unit, the management and control center cuts off electricity supplied to the tool holders.

6. The integrated woodworking system of claim 1, wherein the integrated woodworking system further comprises a screen, the management and control center further comprises a data transmission unit, the screen is electrically connected to one of the tool holders, and the data transmission unit is configured to transmit a file to the screen for display.

7. The integrated woodworking system of claim 6, wherein the data transmission unit transmits the file to the screen wirelessly.

8. The integrated woodworking system of claim 1, wherein the management and control center further comprises a remote electricity management unit controllable by an external computer in order for the management and control center to cut off electricity supplied to the tool holders.

9. The integrated woodworking system of claim 1, further comprising a cutter storage area and a material storage area, both provided in the enclosure.

10. The integrated woodworking system of claim 1, wherein the electricity output cable and the gas output hose are partially embedded in a lateral wall of the enclosure.
